(19) United States
(12) Patent Application Publication
(10) Pub. No.: US 2026/0206161 A1
(43) Pub. Date: Jul. 16, 2026

(54) Disassembly Device for Electronic Parts

(71) Applicant: Tul Corporation, New Taipei City (TW)

(72) Inventor: Chien-Wei Chen, New Taipei City (TW)

(21) Appl. No.: 19/078,581

(22) Filed: Mar. 13, 2025

(30) Foreign Application Priority Data
Jan. 16, 2025 (TW) 114101905

(51) Int. Cl. H05K 7/14

(52) U.S. Cl. CPC H05K 7/1402

(57) ABSTRACT

A disassembly device for electronic parts includes a rectangular rod body, a first end part and a second end part. The first end part has an extending direction parallel to a length direction of the rod body, has a thickness gradually decreasing in a direction away from the rod body. The rod body has a first surface connected to and parallel to the first surface of the first end part, and a second surface connected to the second surface of the first end part with a first included angle formed therebetween greater than 90 degrees and less than 180 degrees. Accordingly, the rectangular rod body can easily reach into a narrow space, and the first end part can accurately push down the push-down latch and disassemble the fixed electronic parts. Furthermore, it is easy to apply force with hands on the rectangular rod body, without damaging the electronic parts.

### CROSS-REFERENCE TO RELATED APPLICATION

This application claims the priority of Taiwanese patent application No. 114101905, filed on January 16, 2025, which is incorporated herewith by reference.

### BACKGROUND OF THE INVENTION

### 1. Field of the Invention

The present invention relates a disassembly device, and particularly, relates to a disassembly device for electronic parts.

### 2. The Prior Arts

A display card is a hardware device used for processing computer images and visual rendering. The display card is responsible for generating images on the computer screen, and is an indispensable component in modern multimedia applications and gaming. The display card includes a graphics processing unit (GPU), a display memory, a heat dissipating system, and a connector interface.

With the advancement of technology, the performance demands for display cards are increasing, which requires more powerful hardware to support, leading to increasing volume of display cards. Specifically, the reasons that the volume of display cards increases includes: first, to improve computing power, the display cards require more transistors, resulting in an increase in chip area; second, the high-performance graphic processing unit leads to a significant amount of heat during operation, requiring larger and more efficient heat dissipating systems to ensure stable operation; third, modern games and professional applications require larger display memory to store high-resolution textures and graphics data; fourth, to provide the electric power needed for high performance, the display cards are equipped with more complex power supply modules with additional multiple power connectors, leading to an increase in the size of the display cards; fifth, high-end display cards often come with built-in LEDs to enhance the aesthetics of the display cards, which occupies certain space; sixth, the larger volume contributes to heat dissipation and electric power stability.

However, since the size of the motherboard is limited, if the volume of the display card increases, it will inevitably causes the reduction of the space between the display card and surrounding parts to decrease. As a result, when users disassemble the display card, their fingers cannot reach into the narrow space between the display card and the surrounding parts to push down a push-down latch or lift up a toggle latch. The users can use a flat-head screwdriver to reach into the narrow space between the display card and the surrounding parts to push down the push-down latch.

However, if the narrow space is too cramped, the cylindrical handle of the flat-head screwdriver will be difficult to reach into the narrow space.

Moreover, the cylindrical handle has a certain width, and the tool head of the flat-head screwdriver is usually located at the center of the bottom of the handle. Therefore, even if the cylindrical handle can reach into the narrow space, due to limitation of the diameter of the cylindrical handle, the tool head will remain distant from the electronic parts, making it difficult to access the push-down latch.

In addition, the flat-head screwdriver is difficult to apply force in the narrow space. If the force is applied incorrectly, the tool head can easily damage the display card.

Furthermore, the tool head of the flat-head screwdriver cannot lift up the toggle latch.

Moreover, the tool head of the flat-head screwdriver is made of metal, which has a hardness greater than that of the display card. As a result, the metal tool head can easily cause damage to the display card.

### SUMMARY OF THE INVENTION

A main objective of the present invention is to provide a disassembly device for electronic parts, which is easy to reach into the narrow space and accurately push down the push-down latch, and can be used to disassemble the electronic parts fixed by a push-down latch.

Another objective of the present invention is to provide a disassembly device for electronic parts that allows users to easily apply force with their hands.

Still another objective of the present invention is to provide a disassembly device for electronic parts, which can be used to disassemble the electronic parts fixed by a toggle latch.

Yet another object of the present invention is to provide a disassembly device for electronic parts that will not scratch the electronic parts.

In order to achieve the above objectives, the present invention provides a disassembly device for electronic parts, which includes a rod body, a first end part and a second end part. The rod body is rectangular, and has a first surface and a second surface, wherein the second surface and the first surface of the rod body are located at opposite sides and parallel to each other. The first end part is provided at one end of the rod body, has an extending direction parallel to a length direction of the rod body, has a thickness gradually decreasing in a direction away from the rod body, and has a first surface and a second surface, wherein the second surface of the first end part is located at an opposite side of the first surface of the first end part, the first surface of the rod body is connected to and parallel to the first surface of the first end part, the second surface of the rod body is connected to the second surface of the first end part with a first included angle formed therebetween, and the first included angle is greater than 90 degrees and less than 180 degrees. The second end part is provided at another end of the rod body.

In some embodiments, a second included angle is formed between an extending direction of the second end part and the length direction of the rod body, and the second included angle is less than or equal to 90 degrees, such that the second end part is hook-shaped.

In some embodiments, the second end part is located at a same side as the first surface of the rod body.

In some embodiments, a rounding is formed at a junction between the second surface of the rod body and the second end part.

In some embodiments, a thickness of the second end part gradually decreases in the direction away from the rod body.

In some embodiments, widths of the rod body, the first end part, and the second end part are equal.

In some embodiments, the rod body, the first end part, and the second end part are made of plastic.

Compared to the flat-head screwdriver, the disassembly device of the present invention offers the following several advantageous effects: first, the rectangular rod body can easily reach into the narrow space, and the first end part can accurately push down the push-down latch, and can be used to disassemble the electronic parts fixed by the push-down latch; second, the users can easily apply force to the rectangular rod body with their hands without causing damage to the electronic parts; third, the second end part can be used to disassemble the electronic parts fixed by the toggle latch; fourth, the rod body, the first end part, and the second end part made of plastic will not scratch the electronic parts.

### BRIEF DESCRIPTION OF THE DRAWINGS

FIG. 1 is a perspective view of the disassembly device of the present invention;

FIG. 2 is a front view of the disassembly device of the present invention;

FIG. 3 is a rear view of the disassembly device of the present invention;

FIG. 4 is a schematic diagram of a motherboard provided with a plurality of display card slots, wherein the latches are of push-down type;

FIG. 5 is a schematic diagram showing that the disassembly device of the present invention reaches into the narrow space between a plurality of display cards and pushes down the latch;

FIG. 6 is a schematic diagram of a motherboard provided with a plurality of display card slots, wherein the latches are of toggle type; and

FIG. 7 is a schematic diagram showing that the disassembly device of the present invention reaches into the narrow space between a plurality of display cards and lifts up the latch.

### DETAILED DESCRIPTION OF THE PREFERRED EMBODIMENT

Embodiments of the present invention will be described in more detail below with reference to the drawings and the reference numerals, such that those skilled in the art can implement it after studying this specification.

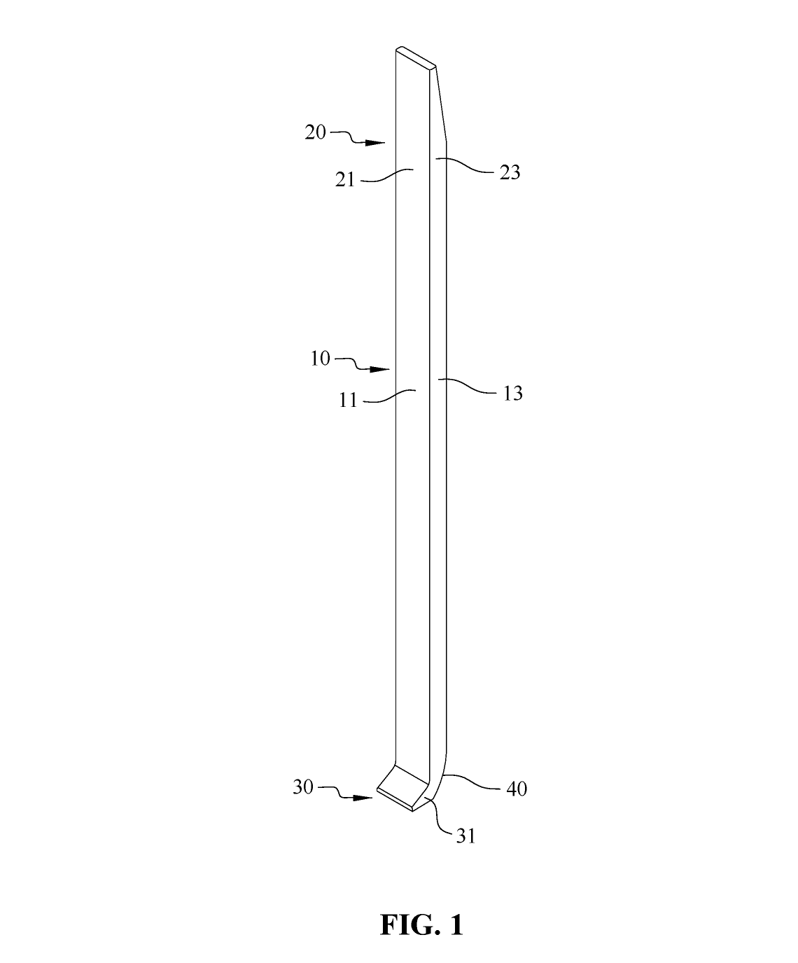

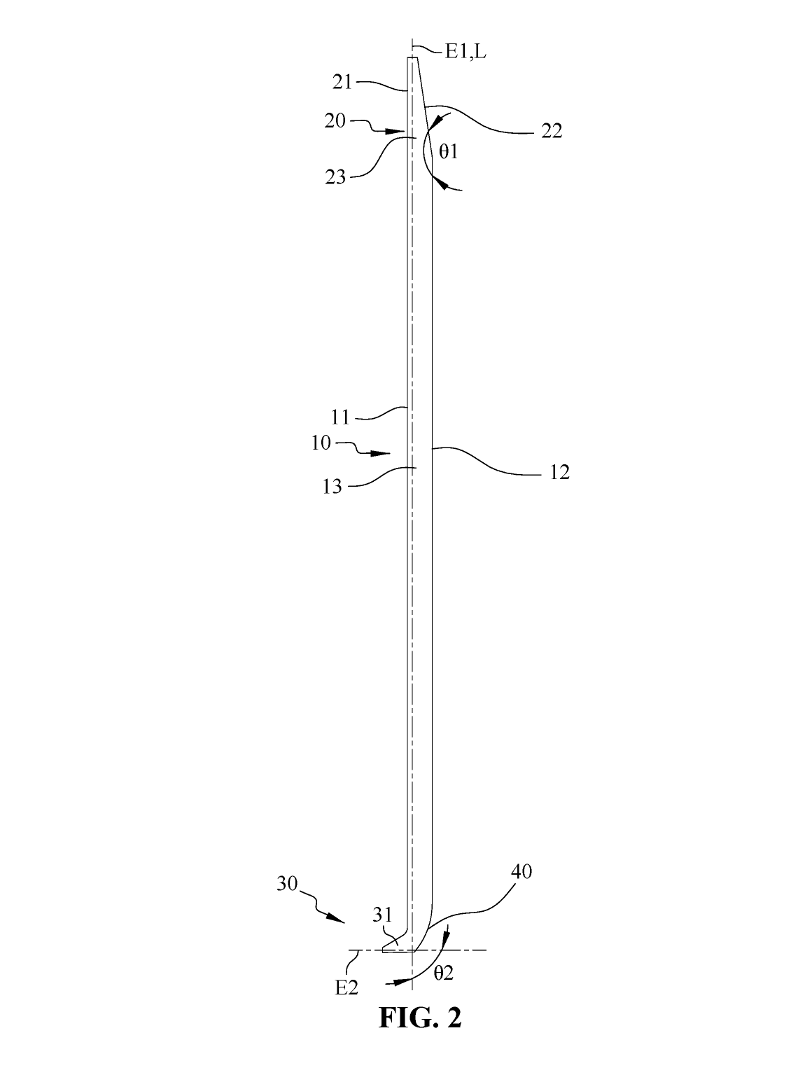

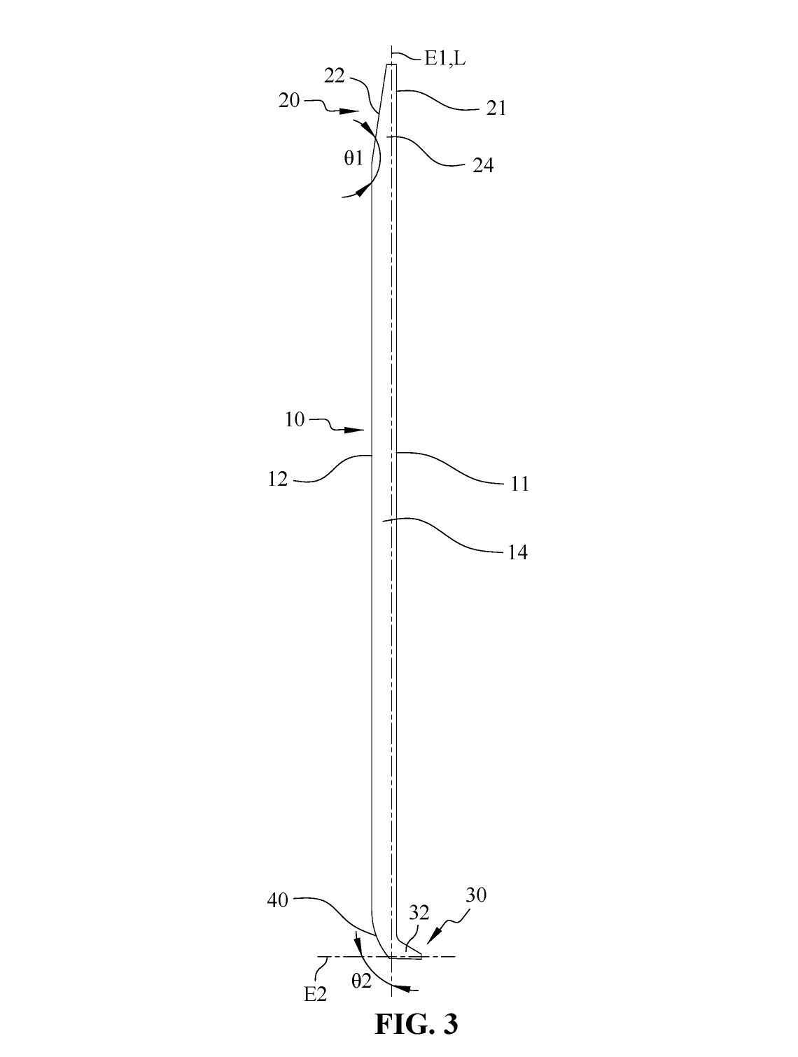

FIG. 1 is a perspective view of the disassembly device of the present invention. FIG. 2 is a front view of the disassembly device of the present invention. FIG. 3 is a rear view of the disassembly device of the present invention. As shown in FIGS. 1, 2 and 3, the present invention provides a disassembly device for electronic parts, which includes a rod body 10, a first end part 20, and a second end part 30. The rod body 10 is rectangular, and has a first surface 11 and a second surface 12. The second surface 12 and the first surface 11 of the rod body 10 are located at opposite sides and parallel to each other. The first end part 20 is provided at one end of the rod body 10, has an extending direction E1 parallel to a length direction L of the rod body 10, has a thickness gradually decreasing in the direction away from the rod body 10, and has a first surface 21 and a second surface 22. The second surface 22 of the first end part 20 is located at the opposite side of the first surface 21 of the first end part 20. The first surface 11 of the rod body 10 is connected to and parallel to the first surface 21 of the first end part 20. The second surface 12 of the rod body 10 is connected to the second surface 22 of the first end part 20 with a first included angle θ₁ formed therebetween. The first included angle θ₁ is greater than 90 degrees and less than 180 degrees. In other words, the first surface 11 of the rod body 10 and the first surface 21 of the first end part 20 are on the same plane. Relative to the first surface 11 and the second surface 12 of the rod body 10 as well as the first surface 21 of the first end part 20, the second surface 22 of the first end part 20 is an inclined surface. The second end part 30 is provided at the other end of the rod body 10, with a second included angle θ₂ formed between an extending direction E2 of the second end part 30 and the length direction L of the rod body 10. The second included angle θ₂ is equal to 90 degrees (i.e., the extending direction E2 of the second end part 30 is perpendicular to the length direction L of the rod body 10), such that the second end part 30 is hook-shaped. In some embodiments, the second included angle θ₂ is less than 90 degrees (i.e., the second end part 30 tilts upward relative to the rod body 10)

The following will illustrate how the disassembly device for electronic parts of the present invention disassembles the electronic parts with reference to the drawings.

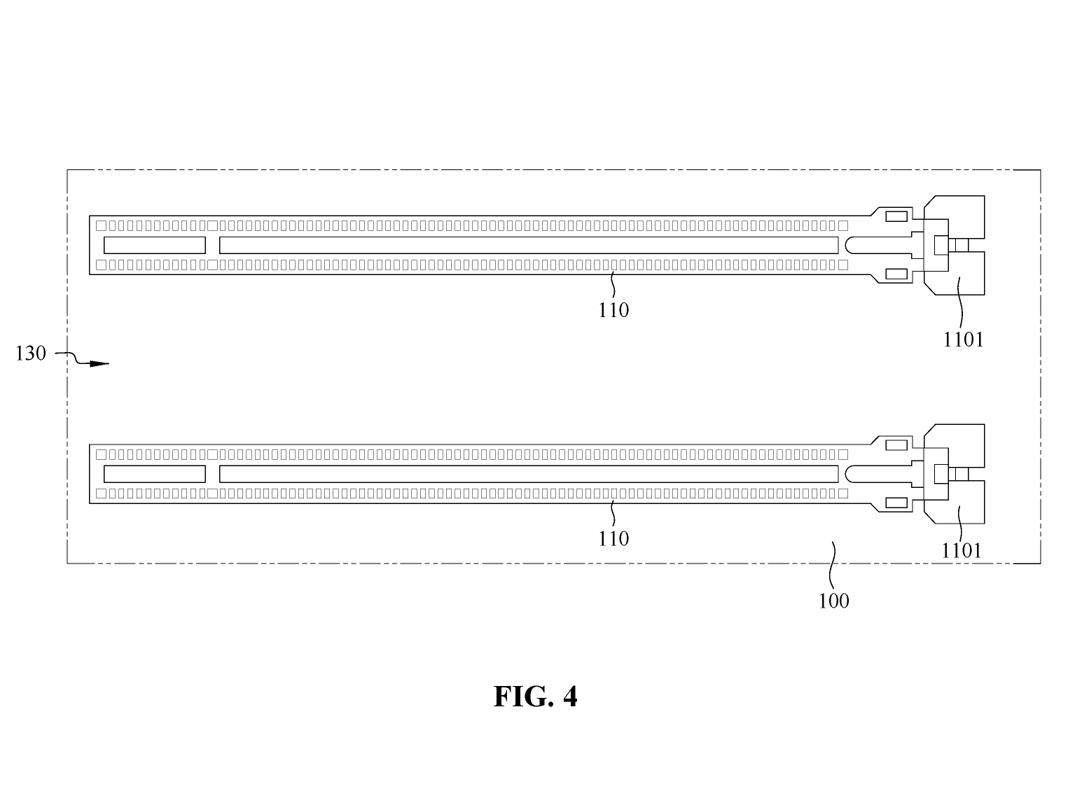

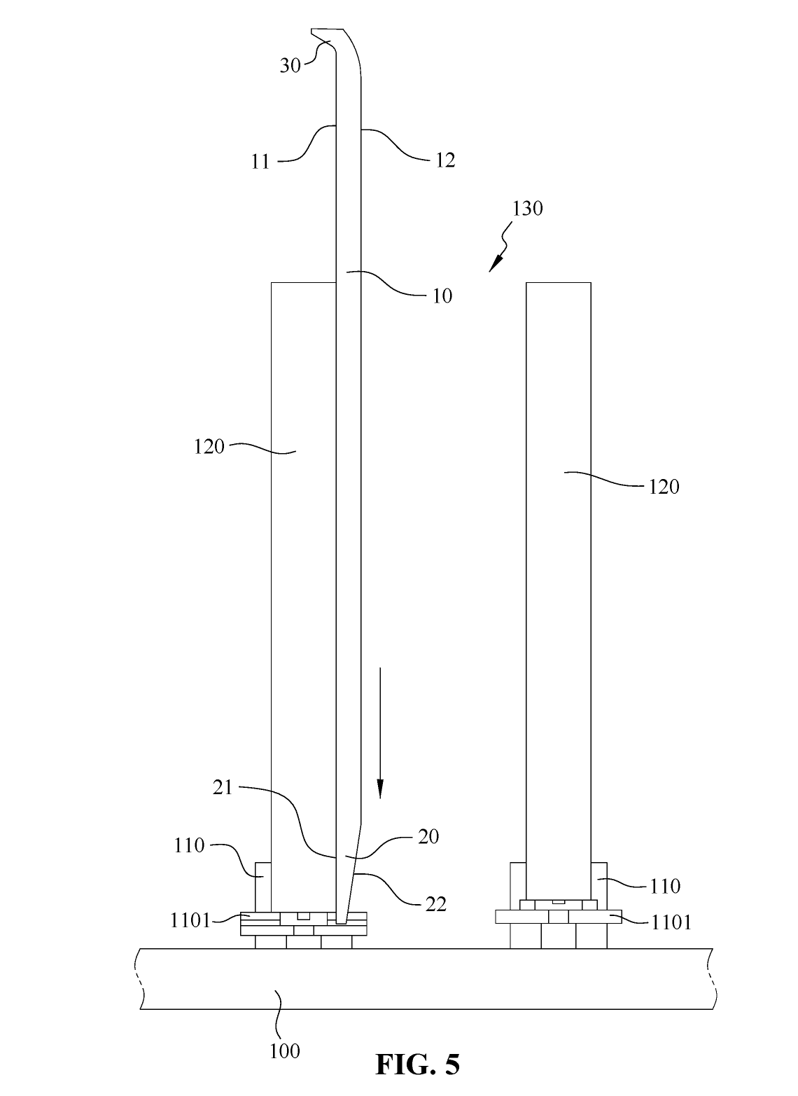

FIG. 4 is a schematic diagram of a motherboard 100 provided with a plurality of display card slots 110, wherein the latches 1101 are of push-down type. FIG. 5 is a schematic diagram showing that the disassembly device of the present invention reaches into the narrow space 130 between a plurality of display cards 120 and pushes down the latch 1101. As shown in FIG. 4, the motherboard 100 is provided with a plurality of display card slots 110, wherein the latch 1101 of each display card slot 110 is of push-down type. As shown in FIG. 5, the plurality of display cards 120 are installed in the display card slots 110, the rod body 10 reaches into the narrow space 130 between the display cards 120. The first surface 11 of the rod body 10 and the first surface 21 of the first end part 20 can easily move down along the surface of one of the display cards 120 in the narrow space 130 between the display cards 120. This allows the first end part 20 to accurately push down the latch 1101 of one of the display card slots 110, making the one of the display cards 120 disengage from the latch 1101 of the one of the display card slots 110, such that the one of the display cards 120 can be removed from the one of the display card slots 110.

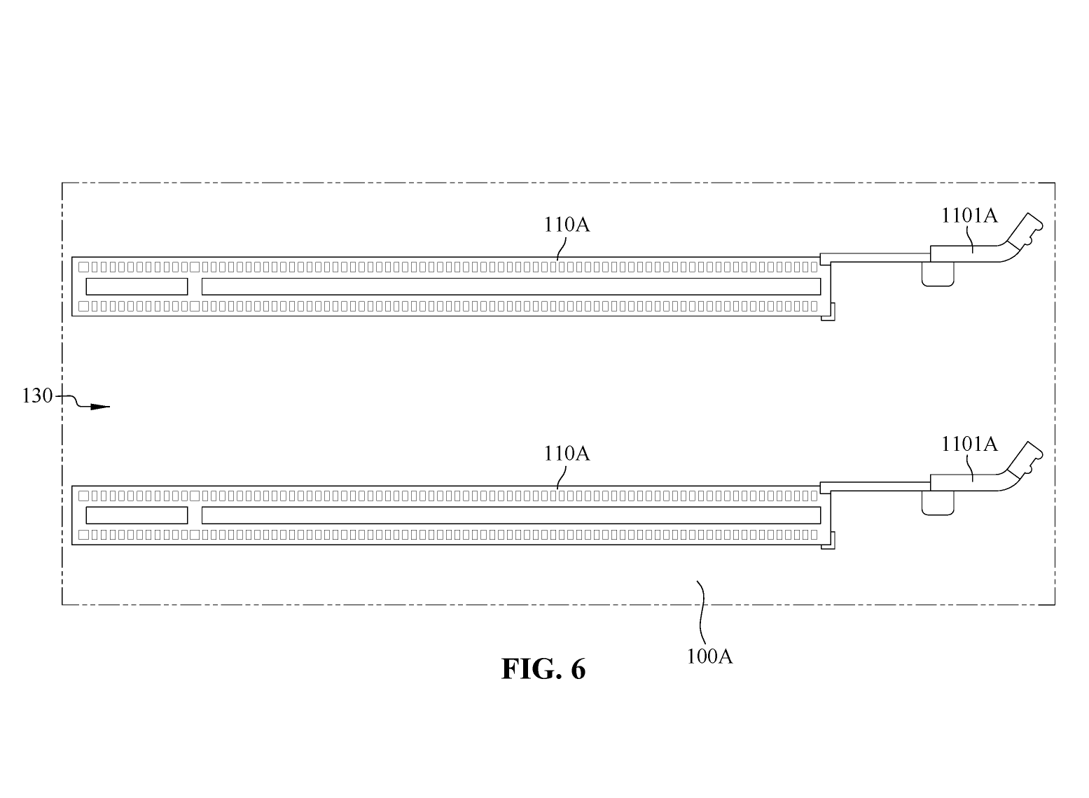

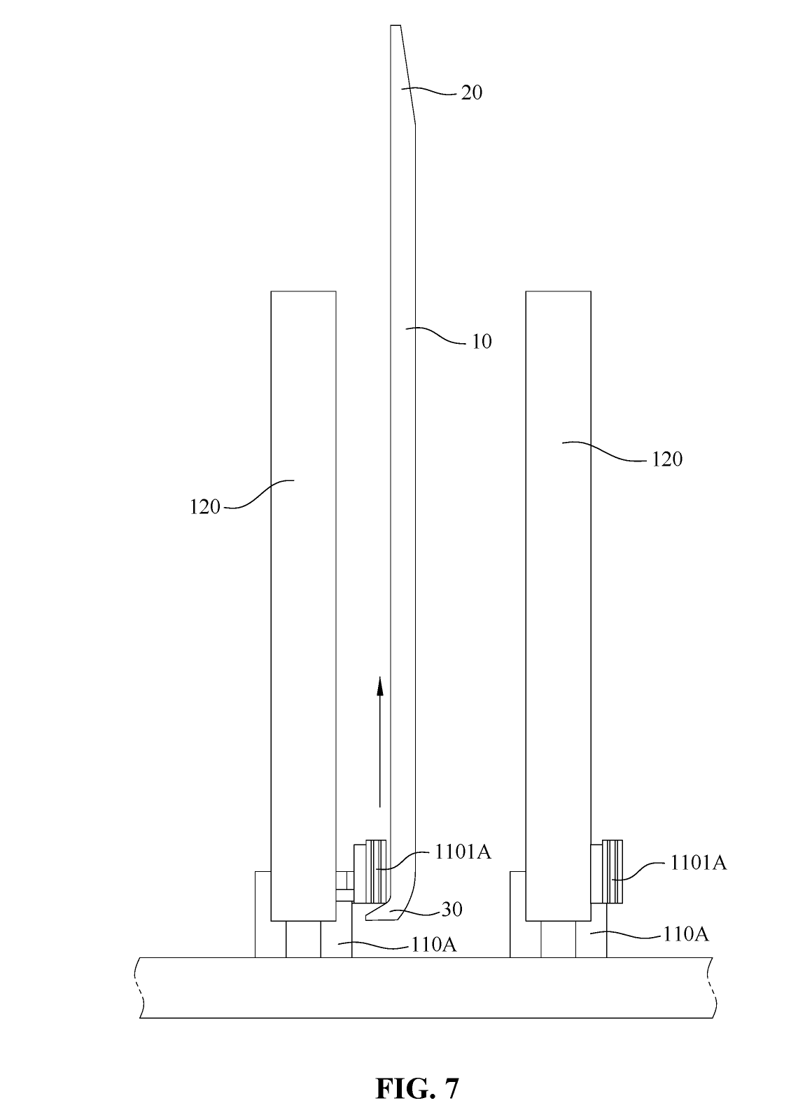

FIG. 6 is a schematic diagram of a motherboard 100 A provided with a plurality of display card slots 110A, wherein the latches 1101A are of toggle type. FIG. 7 is a schematic diagram showing that the disassembly device of the present invention reaches into the narrow space 130 between a plurality of display cards 120 and lifts up the latch 1101A. As shown in FIG. 6, the motherboard 100A is provided with a plurality of display card slots 110A, wherein the latch 1101A of each the display card slot 110A is of toggle type. As shown in FIG. 7, the plurality of display cards 120 are installed in the display card slots 110A, the rod body 10 reaches into the narrow space 130 between the display cards 120, and the second end part 30 lifts up the latch 1101A of one of the display card slots 110A, making one of the display cards 120 disengage from the latch 1101A of the one of the display card slots 110A, such that the one of the display cards 120 can be removed from the one of the display card slots 110A.

The electronic parts in the above embodiment are exemplified by the display cards 120, however, the present invention is not limited thereto. The disassembly device for electronic parts of the present invention can be used to disassemble any electronic part fixed by the pull down latch 1101 or the toggle latch 1101A.

As shown in FIGS. 1, 2 and 3, in the preferred embodiment, the rod body 10 has a first lateral surface 13 and a second lateral surface 14. The second lateral surface 14 and the first lateral surface 13 of the rod body 10 are located at opposite lateral sides and parallel to each other. The first end part 20 has a first lateral surface 23 and a second lateral surface 24, with the second lateral surface 24 of the first end part 20 located at the opposite lateral side of the first lateral surface 23 of the first end part 20. The second end part 30 has a first lateral surface 31 and a second lateral surface 32, with the second lateral surface 32 of the second end part 30 located at the opposite lateral side of the first lateral surface 31 of the second end part 30. The first lateral surface 13 of the rod body 10 is connected to and parallel to the first lateral surface 23 of the first end part 20. The first lateral surface 13 of the rod body 10 is connected to and parallel to the first lateral surface 31 of the second end part 30. The second lateral surface 14 of the rod body 10 is connected to and parallel to the second lateral surface 24 of the first end part 20. The second lateral surface 14 of the rod body 10 is connected to and parallel to the second lateral surface 32 of the second end part 30. In other words, the widths of the rod body 10, the first end part 20, and the second end part 30 are equal.

As shown in FIGS. 1, 2 and 3, in the preferred embodiment, the second end part 30 is located at the same side as the first surface 11 of the rod body 10.

As shown in FIGS. 1, 2 and 3, in the preferred embodiment, a rounding 40 is formed at a junction between the second surface 12 of the rod body 10 and the second end part 30, wherein the rounding 40 can prevent the user's hand from getting injured.

As shown in FIGS. 1, 2 and 3, in the preferred embodiment, the thickness of the second end part 30 gradually decreases in the direction away from the rod body 10. As shown in FIG. 7, the thinner end of the second end part 30 can easily reach into the gap below the toggle latch 1101A.

As shown in FIGS. 1, 2 and 3, in the preferred embodiment, the rod body 10, the first end part 20, and the second end part 30 are made of plastic, which has a lower hardness than metal and is less likely to scratch the electronic parts.

Compared to a flat-head screwdriver, the disassembly device of the present invention offers the following several advantageous effects: first, the rectangular rod body 10 can easily reach into the narrow space 130, and the first end part 20 can accurately push down the push-down latch 1101, and can be used to disassemble the electronic parts fixed by the push-down latch 1101; second, the users can easily apply force to the rectangular rod body 10 with their hands without causing damage to the electronic parts; third, the second end part 30 can be used to disassemble the electronic parts fixed by the toggle latch 1101A; fourth, the rod body 10, the first end part 20, and the second end part 30 made of plastic will not scratch the electronic parts.

Those mentioned above are only preferred embodiments for explaining the present invention, but not intend to limit the present application in any forms, so that any modifications or verification relating to the present invention made in the same spirit of invention should still be included within the scope of the present invention as intended to be protected.

What is claimed is:

1. A disassembly device for electronic parts, includes:
a rod body, which is rectangular, and has a first surface and a second surface, wherein the second surface and the first surface of the rod body are located at opposite sides and parallel to each other;
a first end part, which is provided at one end of the rod body, has an extending direction parallel to a length direction of the rod body, has a thickness gradually decreasing in a direction away from the rod body, and has a first surface and a second surface, wherein the second surface of the first end part is located at an opposite side of the first surface of the first end part, the first surface of the rod body is connected to and parallel to the first surface of the first end part, the second surface of the rod body is connected to the second surface of the first end part with a first included angle formed therebetween, and the first included angle is greater than 90 degrees and less than 180 degrees; and
a second end part, which is provided at another end of the rod body.

2. The disassembly device for electronic parts according to claim 1, wherein a second included angle is formed between an extending direction of the second end part and the length direction of the rod body, and the second included angle is less than or equal to 90 degrees, such that the second end part is hook-shaped.

3. The disassembly device for electronic parts according to claim 2, wherein the second end part is located at a same side as the first surface of the rod body.

4. The disassembly device for electronic parts according to claim 3, wherein a rounding is formed at a junction between the second surface of the rod body and the second end part.

5. The disassembly device for electronic parts according to claim 2, wherein a thickness of the second end part gradually decreases in the direction away from the rod body.

6. The disassembly device for electronic parts according to claim 1, wherein widths of the rod body, the first end part, and the second end part are equal.

7. The disassembly device for electronic parts according to claim 1, wherein the rod body, the first end part, and the second end part are made of plastic.
